(19) United States
(12) Patent Application Publication
(10) Pub. No.: US 2024/0282618 A1
(43) Pub. Date: Aug. 22, 2024

(54) JIG, SEMICONDUCTOR MANUFACTURING APPARATUS, AND METHOD OF OPERATING SEMICONDUCTOR MANUFACTURING APPARATUS

(71) Applicant: Kioxia Corporation, Tokyo (JP)

(72) Inventor: Kentaku ARAI, Mie Mie (JP)

(73) Assignee: Kioxia Corporation, Tokyo (JP)

(21) Appl. No.: 18/433,810

(22) Filed: Feb. 6, 2024

(30) Foreign Application Priority Data
Feb. 20, 2023 (JP) 2023-024371

(51) Int. Cl. H01L 21/687; H01L 21/67

(52) U.S. Cl. CPC H01L 21/68735; H01L 21/67069; H01L 21/68707; H01L 21/68742; H01L 21/68757

(57) ABSTRACT

A jig includes a main body having a form of a semiconductor wafer. A first face of the main body has a groove of a circular form or an arc form. A semiconductor manufacturing apparatus according to the embodiment includes a chamber that houses a semiconductor wafer and processes the semiconductor wafer under reduced pressure. A stage is disposed inside the chamber, and the semiconductor wafer can be placed on the stage. A supply holds the jig which includes the main body having the shape of the semiconductor wafer and the groove provided in the first face of the main body. A transfer unit transfers the jig from the stage to the supply.

### CROSS-REFERENCE TO RELATED APPLICATION (S)

This application is based upon and claims the benefit of priority from Japanese Patent Application No. 2023-024371, filed Feb. 20, 2023, the entire contents of which are incorporated herein by reference.

### FIELD

Embodiments described herein relate generally to a jig, a semiconductor manufacturing apparatus, and a method of operating a semiconductor manufacturing apparatus.

### BACKGROUND

A chamber of a semiconductor manufacturing apparatus may be exposed to the atmosphere from a vacuum state for maintenance. During this kind of maintenance, foreign matter may adhere to a stage on which a wafer is to be placed. This kind of foreign matter may cause variation in a processed dimension or the like of the wafer.

### DESCRIPTION OF THE DRAWINGS

FIG. 1 is a plan view showing an example of a configuration of a jig according to a first embodiment.

FIG. 2 is a side view showing an example of configuration of the jig according to the first embodiment.

FIG. 3 is a schematic plan view showing an example of a configuration of a semiconductor manufacturing apparatus according to the first embodiment.

FIG. 4 is a cross-sectional view showing a dummy wafer container and the jig housed therein.

FIG. 5 is a plan view showing the jig, and a part of an arm robot that transfers the jig.

FIG. 6 is a cross-sectional view showing an example of a configuration of a chamber.

FIG. 7 is a cross-sectional view showing an example of a configuration of the chamber.

FIG. 8 is a drawing showing a comparative example.

FIG. 9 is a drawing showing a state when maintaining the chamber according to the first embodiment.

FIG. 10 is a drawing showing a state when maintaining the chamber according to the first embodiment.

FIG. 11 is a schematic plan view showing a method of operating the semiconductor manufacturing apparatus according to the first embodiment.

FIG. 12 is a schematic plan view showing a method of operating the semiconductor manufacturing apparatus, continued from FIG. 11.

FIG. 13 is a schematic plan view showing a method of operating the semiconductor manufacturing apparatus, continued from FIG. 12.

FIG. 14 is a schematic plan view showing a method of operating the semiconductor manufacturing apparatus, continued from FIG. 13.

FIG. 15 is a schematic plan view showing a method of operating the semiconductor manufacturing apparatus, continued from FIG. 14.

FIG. 16 is a drawing showing a state when maintaining a chamber according to a second embodiment.

### DETAILED DESCRIPTION

In general, according to at least one embodiment, a jig includes a main body having a form (or shape) of a semiconductor wafer. A first face of the main body has a groove of a circular form (or shape) or an arc form (or shape).

Hereafter, embodiments relating to the present disclosure will be described, referring to the drawings. The embodiments do not limit the present disclosure. The drawings are schematic or conceptual. In the specification and the drawings, identical reference signs denote identical elements.

### First Embodiment

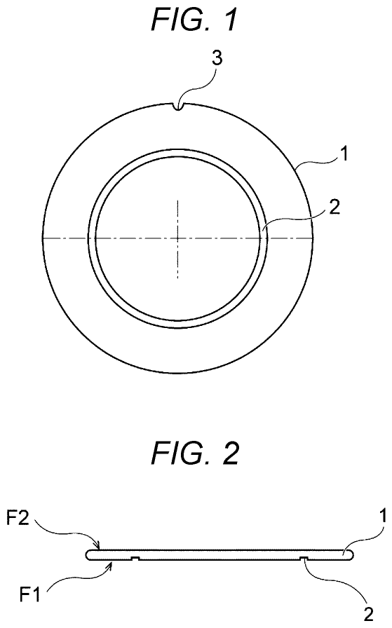

FIG. 1 is a plan view showing an example of a configuration of a jig 1 according to a first embodiment. FIG. 2 is a side view showing an example of a configuration of the jig 1 according to the first embodiment.

The jig 1 is, for example, used in a semiconductor manufacturing apparatus such as a dry etching apparatus. The jig 1 is, for example, used for covering a surface of a stage inside a chamber when maintaining an interior of the chamber of a semiconductor manufacturing apparatus.

As shown in FIGS. 1 and 2, the jig 1 includes a main body having a form of a semiconductor wafer. The jig 1 has a first face F1, and a second face F2 opposite to the first face F1. A groove 2 is provided in the first face F1 of the jig 1. The groove 2 has a circular form, and is depressed from the first face F1 toward the second face F2. A center of the groove 2 approximately corresponds to a center of the main body of the jig 1. The jig 1 is provided with a notch (a cutout) 3 in a part of an outer edge thereof, in the same way as in a semiconductor wafer. A direction of rotation of the jig 1 on the stage can be determined using the notch 3.

The jig 1 can be placed above the stage provided inside the chamber of the semiconductor manufacturing apparatus, with the first face F1 facing the stage. The groove 2 is provided in a position corresponding to a lifting pin that lifts the semiconductor wafer up from the stage in a state in which the jig 1 is placed above the stage. The groove 2 is provided in order to receive the lifting pin, and to position the jig 1 above the stage. Consequently, the groove 2, not being limited to a groove of a circular form, may be a groove of an arc form provided in a position corresponding to the lifting pin.

A material of the jig 1 is one of, for example, ebonite, polystyrene, polypropylene, polyester, an acrylic material, polyethylene, polyethylene terephthalate, celluloid, cellophane, vinyl chloride, polytetrafluoroethylene, nylon, rayon, or silicon, or a combination of these materials. The jig 1 may be of the same form, the same size, and configured with the same material as a semiconductor wafer to be processed in the semiconductor manufacturing apparatus. The jig 1 may be, for example, a semiconductor wafer in which the groove 2 is provided.

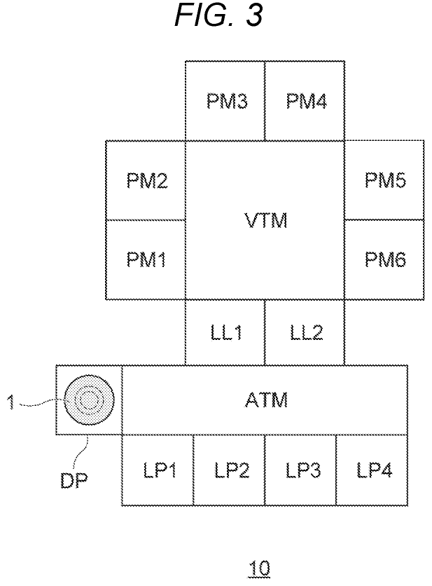

FIG. 3 is a schematic plan view showing an example of a configuration of a semiconductor manufacturing apparatus 10 according to the first embodiment. The semiconductor manufacturing apparatus 10 is, for example, a dry etching apparatus, and processes a semiconductor wafer, or a structural body formed on the semiconductor wafer. However, the semiconductor manufacturing apparatus 10, not being limited to this, may be any apparatus that processes a semiconductor wafer inside an evacuated chamber.

The semiconductor manufacturing apparatus 10 includes chambers PM1 to PM6, a vacuum transfer module VTM, load-lock chambers LL1 and LL2, an atmosphere transfer module ATM, loading ports LP1 to LP4, and a dummy port DP.

Each of the chambers PM1 to PM6 is a vacuum chamber which houses a semiconductor wafer, and in which the semiconductor wafer can be processed. Interiors of the chambers PM1 to PM6 are depressurized using a vacuum pump when processing the semiconductor wafer.

An arm robot (not shown) that transfers a semiconductor wafer or the jig 1 from the load-lock chamber LL1 or LL2 to one of the chambers PM1 to PM6 is provided in the vacuum transfer module VTM. The vacuum transfer module VTM is disposed in a center of the chambers PM1 to PM6 and the load-lock chambers LL1 and LL2 in order that the arm robot can transfer a semiconductor wafer or the jig 1 to any thereof. The vacuum transfer module VTM is depressurized using a vacuum pump, in the same way as the chambers PM1 to PM6.

The load-lock chambers LL1 and LL2 are provided between the vacuum transfer module VTM and the atmosphere transfer module ATM. The load-lock chambers LL1 and LL2 are configured in such a way as to enable a switch between an atmospheric pressure state and a depressurized state. The load-lock chambers LL1 and LL2 are provided in order to transfer a semiconductor wafer or the jig 1 between the vacuum transfer module VTM and the atmosphere transfer module ATM, while maintaining a depressurized state of the vacuum transfer module VTM.

An arm robot (not shown) that transfers a semiconductor wafer or the jig 1 from the loading ports LP1 to LP4 and the dummy port DP to either of the load-lock chamber LL1 or LL2 is provided in the atmosphere transfer module ATM. The atmosphere transfer module ATM is disposed in such a way that the arm robot can transfer a semiconductor wafer or the jig 1 to any of the load-lock chambers LL1 and LL2, the loading ports LP1 to LP4, or the dummy port DP. The load-lock chambers LL1 and LL2, the loading ports LP1 to LP4, and the dummy port DP are disposed in a periphery of the atmosphere transfer module ATM, centered on the atmosphere transfer module ATM. An interior of the atmosphere transfer module ATM is in a state of atmospheric pressure.

The vacuum transfer module VTM and the atmosphere transfer module ATM can transfer a semiconductor wafer or the like from the loading ports LP1 to LP4 or the dummy port DP onto the stage of any of the chambers PM1 to PM6. Also, the vacuum transfer module VTM and the atmosphere transfer module ATM can transfer a semiconductor wafer or the like from the stage of the chambers PM1 to PM6 to any of the loading ports LP1 to LP4 or the dummy port DP.

The loading ports LP1 to LP4 allows a wafer container that houses a semiconductor wafer to be installed in such a way as to be attachable and detachable and allows the semiconductor wafer to be removed from the wafer container. The dummy port DP allows a dummy wafer container that houses a dummy wafer or the like to be installed in such a way as to be attachable and detachable, and allows the dummy wafer to be removed from the dummy wafer container.

In at least one embodiment, the jig 1 is transferred into (supplied to) the semiconductor manufacturing apparatus 10 using the dummy port DP. For example, a dummy wafer container in which the jig 1 is housed is installed in the dummy port DP. The arm robot of the atmosphere transfer module ATM removes the jig 1 from the dummy wafer container, and transfers the jig 1 to the load-lock chamber LL1 or LL2.

In addition, the jig 1 may be transferred into the semiconductor manufacturing apparatus 10 using one of the loading ports LP1 to LP4. In this case, the jig 1 is housed in a wafer container, and the wafer container is installed in one of the ports LP1 to LP4. The arm robot of the atmosphere transfer module AT may remove the jig 1 from the wafer container of one of the loading ports LP1 to LP4, and transfer the jig 1 to the load-lock chamber LL1 or LL2.

Also, a container that houses the jig 1 may be attached to the dummy port DP. In this case, the jig 1 is stored in advance in the container attached to the dummy port DP, and when carrying out maintenance, the vacuum transfer module VTM and the atmosphere transfer module ATM transfer the jig 1 from the container of the dummy port DP to the chambers PM1 to PM6. After maintenance is finished, the vacuum transfer module VTM and the atmosphere transfer module ATM transfer the jig 1 from the chambers PM1 to PM6 to the container of the dummy port DP.

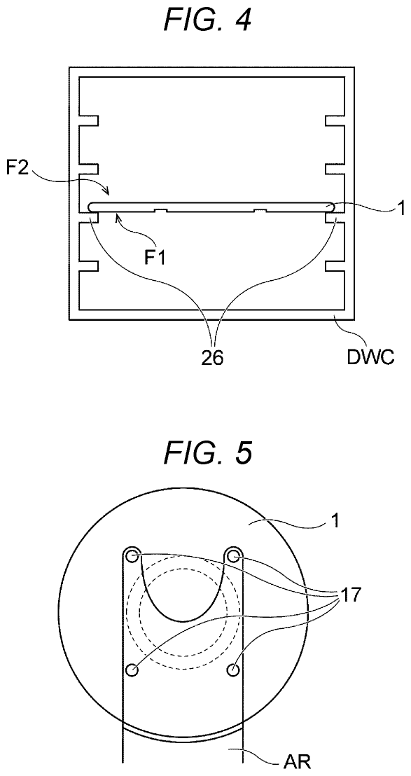

FIG. 4 is a cross-sectional view showing a dummy wafer container DWC and the jig 1 housed therein. The dummy wafer container DWC supports both end portions of the jig 1 with a protruding portion 26 that protrudes from an inner side face of a housing. In order that an arm robot can lift up and transfer the jig 1, the dummy wafer container DWC does not come into contact with a central portion of the jig 1.

FIG. 5 is a plan view showing the jig 1, and a part of an arm robot AR that transfers the jig 1. The arm robot AR lifts the jig 1 inside the dummy wafer container DWC up from the first face F1, and transfers the jig 1. For example, the arm robot AR has a pad 17 on a surface, and the jig 1 is transferred by the pad 17 being brought into contact with the first face F1 of the jig 1.

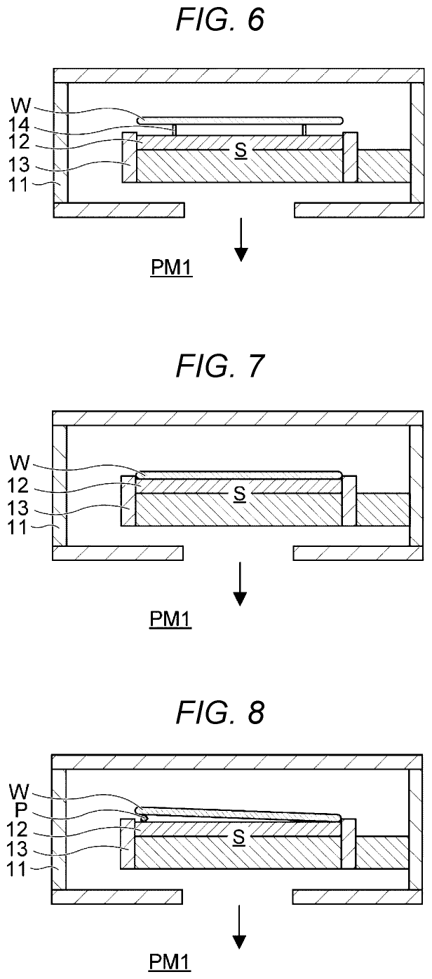

FIGS. 6 and 7 are cross-sectional views showing an example of a configuration of the chamber PM1. FIG. 6 shows a state in which a semiconductor wafer W is being lifted above a stage 12 using a lifting pin 14. FIG. 7 shows a state in which the semiconductor wafer W is placed on the stage 12. Note that the chambers PM2 to PM6 have the same configuration as the chamber PM1. Consequently, an example of a configuration of the chamber PM1 is shown in FIGS. 6 and 7, and a depiction of configurations of the chambers PM2 to PM6 is omitted.

The chamber PM1 includes a frame 11. The stage 12, an edge ring 13, and the lifting pin 14 are provided inside the frame 11 of the chamber PM1. Piping that communicates with a vacuum pump is connected to a bottom portion of the frame 11. Accordingly, an inside of the chamber PM1 is evacuated, as indicated by arrows in FIGS. 6 and 7, and depressurized. Also, a processing gas used in a processing of the semiconductor wafer W is discharged via the piping.

The stage 12 is provided inside the chamber PM1, and is configured in such a way that the semiconductor wafer W can be placed thereon. The stage 12 may be such that, for example, the semiconductor wafer W is fixed using an electrostatic chuck (ESC) provided in an upper portion of a stage main body S.

The edge ring 13 is provided in a periphery of the stage 12, and protrudes somewhat farther than an upper face of the stage 12. Accordingly, the edge ring 13 restricts a deviation of the semiconductor wafer W from the stage 12, and protects an edge of the semiconductor wafer W on the stage 12.

The lifting pin (supporting member) 14 protrudes from the upper face of the stage 12 in order to lift the semiconductor wafer W up from the upper face of the stage 12, as shown in FIG. 6, or withdraws below the upper face of the stage 12 in order to place the semiconductor wafer W on the stage 12, as shown in FIG. 7. In this way, the lifting pin 14 can move up and down in the upper face of the stage 12. The lifting pin 14 may be driven and controlled by an unshown drive unit and controller.

FIG. 8 is a drawing showing a comparative example. When maintaining the chamber PM1, the chamber PM1 is exposed to atmospheric pressure and maintenance is carried out, after which the chamber PM1 is evacuated again, thereby being returned to a depressurized state. When evacuating the chamber PM1 after exposure to the atmosphere in this way, foreign matter P may adhere to the stage 12. For example, when the foreign matter P adheres to the stage 12, the semiconductor wafer W, which is subsequently a subject of processing, locally rises up from the stage 12 when placing the semiconductor wafer W on the stage 12 in processing the semiconductor wafer W. This leads to variation in processing of the semiconductor wafer W.

For example, when the foreign matter P is between the semiconductor wafer W and the stage 12, a gap is formed between the semiconductor wafer W and the stage 12, as shown in FIG. 8. This gap prevents heat of the semiconductor wafer W caused by plasma from being dissipated to the stage 12. That is, the gap causes a cooling capacity of the stage 12 to decrease. This causes a localized variation in processing of the semiconductor wafer W, and leads to variation in dimensions of the semiconductor wafer W. In order to remove this kind of foreign matter P in the chamber PM1, exposure to the atmosphere of the chamber PM1, cleaning of the stage 12, and evacuation need to be executed again.

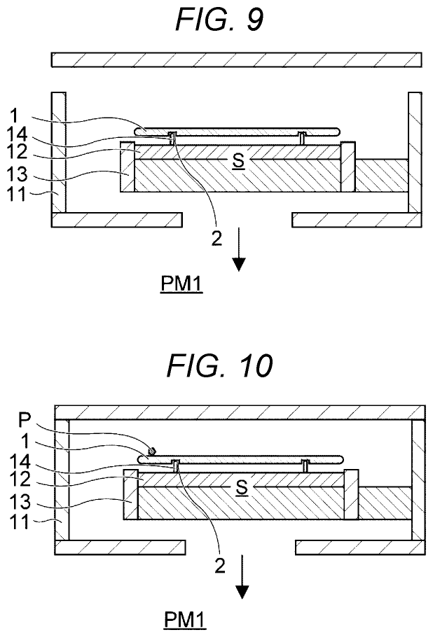

In contrast, in the present embodiment, when the chamber PM1 is exposed to atmospheric pressure and the chamber PM1 is evacuated during maintenance, the jig 1 is placed above the stage 12, covering the upper face of the stage 12, as shown in FIG. 9. This means that even when the foreign matter P appears inside the chamber PM1 in evacuating after exposing the chamber PM1 to the atmosphere, the foreign matter P adheres to the jig 1, but does not adhere to the stage 12, as shown in FIG. 10.

FIGS. 9 and 10 are drawings showing states when maintaining the chamber PM1 according to the first embodiment. The jig 1 is supported above the stage 12 by the lifting pin 14, without coming into contact with the upper face of the stage 12. The lifting pin 14 supports the jig 1 in a state inserted in the groove 2 of the jig 1. That is, the groove 2 of the jig 1 is provided in a position to receive the lifting pin 14 in a state placed above the stage 12. The lifting pin 14 is provided in a position to be inserted in the groove 2 in a state in which the jig 1 is placed above the stage 12. A central axis of the jig 1 is disposed in such a way as to approximately correspond with a central axis of the stage 12 in a state wherein the lifting pin 14 is inserted in the groove 2 of the jig 1. For example, when depressurizing the chamber PM1 after exposing the chamber PM1 to the atmosphere and carrying out maintenance (for example, replacement of the edge ring 13), the jig 1 is placed on the lifting pin 14 caused to protrude from the upper face of the stage 12, as shown in FIG. 9. Accordingly, since the jig 1 covers the upper face of the stage 12, even when the foreign matter P appears inside the chamber PM1 in evacuating after exposing the chamber PM1 to the atmosphere, the foreign matter P adheres to the jig 1, but does not adhere to the stage 12, as shown in FIG. 10. Also, at this time, the jig 1 is placed on the lifting pin 14 in such a way that a tip of the lifting pin 14 is inserted into the groove 2 of the jig 1. Thereby, the jig 1 may be fixed with substantially no deviation from above the stage 12. Also, contact of the jig 1 with the edge ring 13 can be restricted.

After the chamber PM1 reaches a depressurized state, the vacuum transfer module VTM and the atmosphere transfer module ATM transfer the jig 1 from above the stage 12 to the dummy port DP, and house the jig 1 in the dummy wafer container DWC. Thereby, the foreign matter P is removed from the chamber PM1 together with the jig 1. As a result of this, variation in processing of the semiconductor wafer W, which is a processing target subsequently transferred from one of the loading ports LP1 to LP4 and placed above the stage 12, can be restricted.

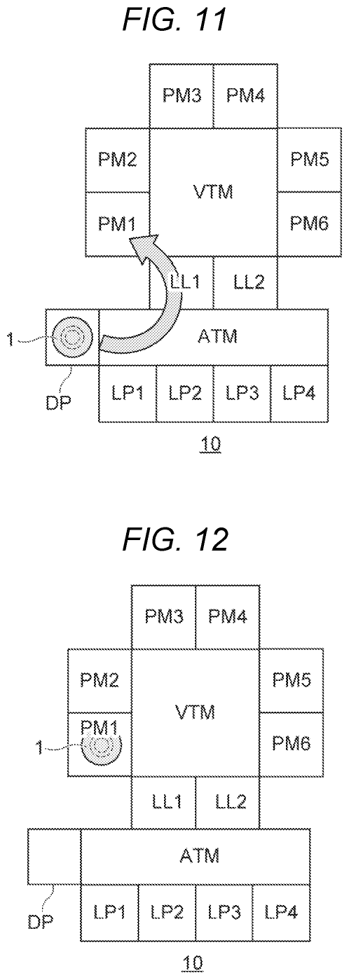

An operation of the semiconductor manufacturing apparatus 10 will be described hereafter in further detail, referring to FIGS. 11 to 15.

FIGS. 11 to 15 are schematic plan views showing a method of operating the semiconductor manufacturing apparatus 10 according to the first embodiment.

When carrying out maintenance of the chamber PM1, the dummy wafer container DWC housing the jig 1 is installed in the dummy port DP. When the semiconductor manufacturing apparatus 10 includes a container that houses the jig 1 in the dummy port DP, the jig 1 may be supplied to the semiconductor manufacturing apparatus 10 by storing the jig 1 in advance in the container of the dummy port DP, and a supply of the jig 1 to the semiconductor manufacturing apparatus 10 using the dummy wafer container DWC is unnecessary.

Next, before exposing the chamber PM1 to atmospheric pressure, the vacuum transfer module VTM and the atmosphere transfer module ATM transfer the jig 1 from the dummy port DP to above the stage 12 of the chamber PM1, and place the jig 1 on the lifting pin 14, as shown in FIGS. 11 and 12. At this time, the lifting pin 14 is in a state protruding from the upper face of the stage 12 in the chamber PM1.

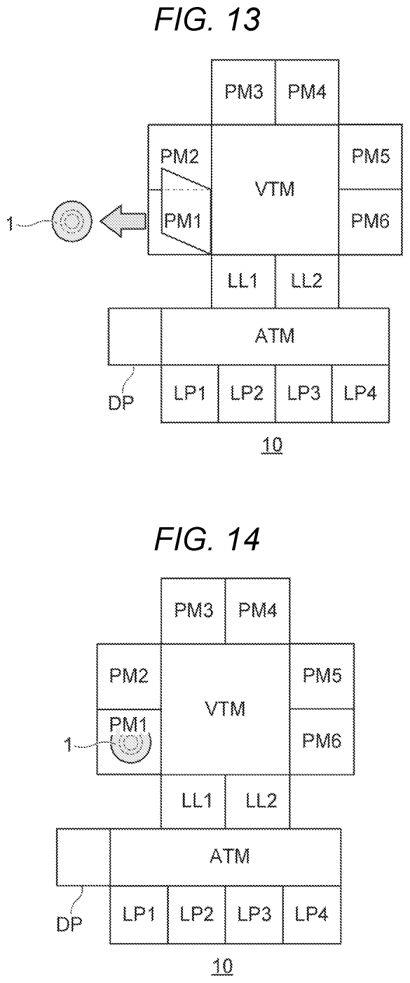

Next, the chamber PM1 is exposed to atmospheric pressure, and maintenance is carried out. At this time, an operator causes the jig 1 to temporarily withdraw from the chamber PM1, as shown in FIG. 13. The maintenance is, for example, a replacement of the edge ring 13 provided in the periphery of the stage 12. When, for example, cleaning of the stage 12 during maintenance can be rendered unnecessary, and withdrawal of the jig 1 becomes unnecessary, owing to the upper face of the stage 12 being covered by the jig 1 before and after maintenance, the jig 1 may remain placed on the lifting pin 14 even during maintenance.

After maintenance is finished, the operator returns the jig 1 onto the lifting pin 14 of the chamber PM1 before evacuating the chamber PM1. Subsequently, as shown in FIG. 14, the operator returns the chamber PM1 to an airtight state, and carries out evacuation of the inside of the chamber PM1. Even if foreign matter appears at this time, the foreign matter adheres to the jig 1, and is unlikely to adhere to the stage 12.

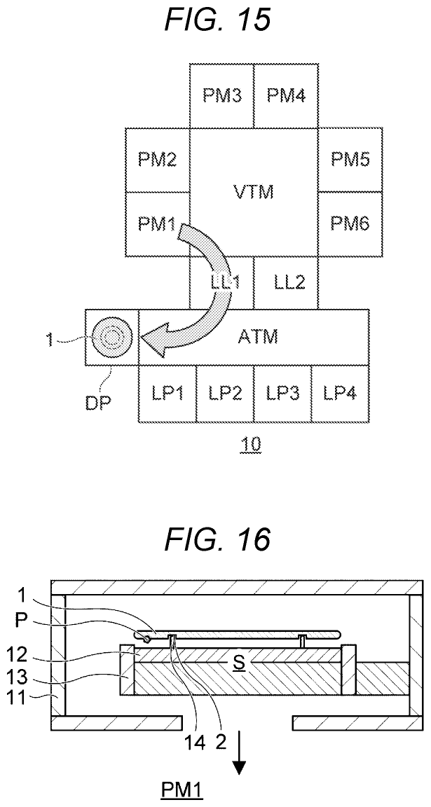

After the chamber PM1 reaches a depressurized state, the vacuum transfer module VTM and the atmosphere transfer module ATM transfer the jig 1 from above the stage 12 to the dummy port DP, and house the jig 1 in the dummy wafer container DWC, as shown in FIG. 15. Accordingly, foreign matter is removed from the chamber PM1 together with the jig 1.

When there is no need to place the jig 1 above the stage 12 in exposing the chamber PM1 to the atmosphere, the operator may place the jig 1 on the lifting pin 14 after exposing the chamber PM1 to atmospheric pressure and carrying out maintenance, without the vacuum transfer module VTM and the atmosphere transfer module ATM transferring the jig 1 to the chamber PM1 before exposure to the atmosphere. In this case, the processes of FIGS. 11 to 13 are omitted, and the operator may start from placing the jig 1 on the lifting pin 14 (FIG. 14) after exposing the chamber PM1 to atmospheric pressure and carrying out maintenance. In this way, the jig 1 can also remove foreign matter appearing when evacuating the chamber PM1.

Maintenance of the chambers PM2 to PM6 may also be executed in the same way as the maintenance of the chamber PM1.

The jig 1 according to the present embodiment can restrict adhering of foreign matter onto the stage 12 when switching the chambers PM1 to PM6 from a state exposed to the atmosphere to a depressurized state. Thereby, no gap is formed between the semiconductor wafer W that is a processing target and the stage 12, and variation in a processing of the semiconductor wafer W can be restricted.

### Second Embodiment

In a second embodiment, a material of the jig 1 is one of, for example, ebonite, polystyrene, polypropylene, polyester, an acrylic material, polyethylene, polyethylene terephthalate, celluloid, cellophane, vinyl chloride, or polytetrafluoroethylene, which are negatively charged, or one of nylon or rayon, which are positively charged, or a combination of these materials. In this case, the jig 1 may adsorb foreign matter using static electricity.

FIG. 16 is a drawing showing a state when carrying out maintenance of the chamber PM1 according to the second embodiment. The jig 1 being supported above the stage 12 by the lifting pin 14, without coming into contact with the upper face of the stage 12, is the same as in the first embodiment. Since the jig 1 covers the upper face of the stage 12, even when the foreign matter P appears inside the chamber PM1 in evacuating after exposing the chamber PM1 to the atmosphere, the foreign matter P adheres to the jig 1, but does not adhere to the stage 12. Also, the lifting pin 14 supports the jig 1 in a state inserted into the groove 2 of the jig 1. Accordingly, the jig 1 may be fixed with substantially no deviation from above the stage 12. Also, the jig 1 coming into contact with the edge ring 13 is restricted, whereby damage to the edge ring 13 can be restricted.

Furthermore, in the second embodiment, the jig 1 is negatively or positively charged. For example, the jig 1 is charged by friction between the jig 1 and the protruding portion 26 of FIG. 4 when being removed from the dummy wafer container DWC, or by friction between the jig 1 and the pad 17 of the arm robot AR. Thereby, the jig 1 can adsorb the foreign matter P on the stage 12 using electrostatic electricity when the jig 1 is placed above the stage 12. In this way, according to the second embodiment, the jig 1 can adsorb not only the foreign matter P that falls (floats down) from above the stage 12, but also the foreign matter P on the stage 12, and remove the foreign matter P from the chamber PM1.

Other configurations and operations of the second embodiment may be the same as the corresponding configurations and operations of the first embodiment. Consequently, the second embodiment is such that the advantages of the first embodiment can also be obtained.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A jig comprising:
a main body having a shape of a semiconductor wafer, the main body having a first face, wherein the first face has a groove of a circular shape or an arc shape.

2. The jig according to claim 1, wherein a center of the circle or the arc of the groove substantially corresponds to a center of the main body.

3. The jig according to claim 1, wherein the main body is disposed inside a chamber of a semiconductor manufacturing apparatus that is arranged to process a semiconductor wafer, the main body being arranged to be placed above a stage on which the semiconductor wafer is placed, with the first face facing the stage, and
the groove is disposed in a position corresponding to a support configured to lift the semiconductor wafer up from the stage, in a state in which the main body is placed above the stage.

4. The jig according to claim 1, wherein a material of the main body is one of ebonite, polystyrene, polypropylene, polyester, an acrylic material, polyethylene, polyethylene terephthalate, celluloid, cellophane, vinyl chloride, polytetrafluoroethylene, nylon, or rayon, or a combination of these materials.

5. A semiconductor manufacturing apparatus, comprising:
a chamber configured to house a semiconductor wafer and process the semiconductor wafer under reduced pressure;
a stage disposed inside the chamber, the stage being configured to support the semiconductor wafer;
a supply for holding a jig, the jig having a main body that has a shape of the semiconductor wafer and a groove provided in a first face of the main body; and
a transfer unit configured to transfer the jig from the stage to the supply.

6. The semiconductor manufacturing apparatus according to claim 5, wherein the groove has a circular shape or an arc shape, and
a center of the circle or the arc of the groove substantially corresponds to a center of the main body of the jig.

7. The semiconductor manufacturing apparatus according to claim 5, further comprising a support configured to lift the semiconductor wafer up from the stage, wherein
the groove is disposed in a position such that the support is inserted in a state in which the jig is placed above the stage.

8. The semiconductor manufacturing apparatus according to claim 5, wherein the jig is arranged to be placed above the stage when depressurizing the chamber after exposing the chamber to atmospheric pressure.

9. The semiconductor manufacturing apparatus according to claim 7, wherein the jig is supported above the stage by the support in a state in which the support is inserted into the groove.

10. The semiconductor manufacturing apparatus according to claim 5, wherein the transfer unit is configured to transfer the jig from above the stage to the supply after the chamber is depressurized.

11. The semiconductor manufacturing apparatus according to claim 5, wherein the transfer unit is configured to transfer the jig from the supply to above the stage before the chamber is exposed to atmospheric pressure.

12. The semiconductor manufacturing apparatus according to claim 5, wherein the supply is a port in which a container housing the jig is installed.

13. A method of operating a semiconductor manufacturing apparatus comprising a chamber, which houses a semiconductor wafer and processes the semiconductor wafer under reduced pressure, and a stage disposed inside the chamber, the stage being arranged to support the semiconductor wafer, the method comprising:
placing a jig above the stage inside the chamber that is exposed to atmospheric pressure, the jig having a main body that has a shape of the semiconductor wafer and a groove provided in a first face of the main body, and
depressurizing the chamber after the jig is placed above the stage.

14. The method according to claim 13, wherein the semiconductor manufacturing apparatus further comprises a support configured to lift the semiconductor wafer up from the stage, the groove being disposed in a position such that the support is inserted in a state in which the jig is placed above the stage, and
the support is inserted into the groove of the jig when the jig is placed above the stage, and the jig is supported by the support.

15. The method according to claim 13, wherein the semiconductor manufacturing apparatus further comprises a supply that holds the jig, and a transfer unit configured to transfer the jig from above the stage to the supply, and the method further comprising
transferring the jig from above the stage to the supply after the chamber is depressurized.

16. The method according to claim 15, further comprising transferring the jig from the supply to above the stage before the chamber is exposed to atmospheric pressure.

17. The method according to claim 16, further comprising placing the jig supplied to above the stage on a support such that the support, which protrudes from an upper face of the stage, is inserted into the groove.

18. The method according to claim 13, wherein an edge ring disposed in a periphery of the stage is replaced after exposing the chamber to atmospheric pressure, and before depressurizing.

19. The method according to claim 13, wherein a material of the main body of the jig is one of ebonite, polystyrene, polypropylene, polyester, an acrylic material, polyethylene, polyethylene terephthalate, celluloid, cellophane, vinyl chloride, polytetrafluoroethylene, nylon, or rayon, or a combination of these materials.

20. The method according to claim 13, wherein a material of the main body is silicon.
